(19) United States
(12) Patent Application Publication
(10) Pub. No.: US 2026/0068544 A1
(43) Pub. Date: Mar. 5, 2026

(54) PHASE-CHANGE MEMORY DEVICE AND MANUFACTURING METHOD THEREOF

(71) Applicant: NANYA TECHNOLOGY CORPORATION, New Taipei City (TW)

(72) Inventor: Wei-Chuan FANG, New Taipei City (TW)

(21) Appl. No.: 18/823,637

(22) Filed: Sep. 3, 2024

(51) Int. Cl. H10N 70/00; H10B 63/10; H10N 70/20

(52) U.S. Cl. CPC H10N 70/841; H10B 63/10; H10N 70/011; H10N 70/231; H10N 70/823

(57) ABSTRACT

A phase-change memory device includes a substrate, a first electrode, a second electrode, a first carbon layer, a second carbon layer, and a phase-change memory layer. The first electrode and the second electrode are disposed on the substrate and spaced apart from each other. The first carbon layer and the second carbon layer are disposed on the substrate and spaced apart from each other. The first carbon layer and the second carbon layer are respectively electrically connected to the first electrode and the second electrode and are respectively a doped carbon nanotube layer or a doped graphene layer. The phase-change memory layer is disposed between the first carbon layer and the second carbon layer.

### BACKGROUND

### Field of the Invention

The present disclosure relates to a phase-change memory device and a manufacturing method thereof.

### Description of Related Art

Recently, phase-change memory devices have gradually received more attention due to their advantages, such as low power consumption, fast read/write speeds, high capacities, robust endurance, easy embeddedness in logic integrated circuits (ICs), and low costs. The phase-change memory devices can be used for manufacturing non-volatile memories because they can store data by switching the phase of phase-change memory materials between their amorphous and crystalline states. However, the phase-change memory devices are usually required high programming current, which influences their applicability.

### SUMMARY

The present disclosure provides a phase-change memory (PCM) device including a substrate, a first electrode, a second electrode, a first carbon layer, a second carbon layer, and a phase-change memory layer. The first electrode and the second electrode are disposed on the substrate and spaced apart from each other. The first carbon layer and the second carbon layer are disposed on the substrate and spaced apart from each other. The first carbon layer and the second carbon layer are respectively electrically connected to the first electrode and the second electrode and are respectively a doped carbon nanotube layer or a doped graphene layer. The phase-change memory layer is disposed between the first carbon layer and the second carbon layer.

In some embodiments, the phase-change memory layer includes GeTe, SbTe, BiTe, SnTe, AsTe, GeSe, SbSe, BiSe, SnSe, AsSe, InSe, InSb, InSbTe, GeSbTe, AglnSbTe, SiGeSb, TeGeSbS, AgSbSe, GeSbMnSn, AgSbTe, AuSbTe, AlSb, CrGeTe, CuGeTe, ScSbTe, VO₂, MoO₂, V₂O₃, NbO₂, Fe₃O₄, FeS, Ta₂O₅, Ti₃O₅, Ti₂O₃, LaCoO₃, SmNiO₃, or combinations thereof.

In some embodiments, the first carbon layer and the second carbon layer respectively includes a plurality of carbon nanotubes with a length of 10 nm to 90 nm.

In some embodiments, thicknesses of the first carbon layer and the second carbon layer are respectively 100 nm to 500 nm.

In some embodiments, the first carbon layer includes a plurality of carbon nanotubes extending from the first electrode substantially along a first axial direction, and the second carbon layer respectively includes a plurality of carbon nanotubes extending from the second electrode substantially along a second axial direction.

In some embodiments, the first carbon layer is in contact with the first electrode, and the second carbon layer is in contact with the second electrode.

In some embodiments, a closest distance between the first carbon layer and the second carbon layer is less than or equal to 100 nm.

In some embodiments, dopant concentrations of the first carbon layer and the second carbon layer are respectively 3 at % to 10 at %.

In some embodiments, the first carbon layer and the second carbon layer are respectively nitrogen-doped (N-doped) or phosphorus-doped.

In some embodiments, the first electrode and the second electrode respectively includes a Ti layer and a metal layer on the Ti layer, and the metal layer is a Pd layer, an Ag layer, or an Au layer.

The present disclosure provides a method of manufacturing a phase-change memory device including the following operations. A first electrode and a second electrode are formed on a substrate, in which the first electrode and the second electrode are spaced apart from each other. A first carbon layer and a second carbon layer are formed on the substrate, in which the first carbon layer and the second carbon layer are spaced apart from each other, are respectively electrically connected to the first electrode and the second electrode, and are respectively a doped carbon nanotube layer or a doped graphene layer. A phase-change memory layer is formed between the first carbon layer and the second carbon layer.

In some embodiments, forming the first carbon layer and the second carbon layer is performed by plasma-enhanced chemical vapor deposition (PECVD).

In some embodiments, forming the first carbon layer and the second carbon layer includes the followings operations. The first electrode including a first Ti layer and the second electrode including a second Ti layer are formed on the substrate. A plurality of carbon nanotubes extending from the first Ti layer is grew to form the first carbon layer. A plurality of carbon nanotubes extending from the second Ti layer is grew to form the second carbon layer.

In some embodiments, the first carbon layer and the second carbon layer are respectively nitrogen-doped or phosphorus-doped.

In some embodiments, forming the phase-change memory layer between the first carbon layer and the second carbon layer includes forming the phase-change memory layer to cover upper surfaces and side surfaces of the first carbon layer and the second carbon layer.

In some embodiments, a closest distance between the first carbon layer and the second carbon layer is less than or equal to 100 nm.

### BRIEF DESCRIPTION OF THE DRAWINGS

The present disclosure can be more fully understood by reading the following detailed description of the embodiments, with reference made to the accompanying drawings.

FIG. 1 is a flowchart of a method of manufacturing a phase-change memory device according to various embodiments of the present disclosure.

FIG. 2A, FIG. 3A, and FIG. 4A are perspective views illustrating intermediate stages of manufacturing a phase-change memory device according to various embodiments of the present disclosure.

FIG. 2B, FIG. 3B, and FIG. 4B are respectively cross-sectional views of the phase-change memory device during the manufacturing process along the section lines A-A′ in FIG. 2A, FIG. 3A, and FIG. 4A.

FIG. 3C is a top view of the phase-change memory device of FIG. 3A.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

Phase-change memory devices usually require a large current for the reset operation by melting the phase-change material into an amorphous phase, which deteriorates the energy efficiency. The present disclosure provides a phase-change memory device and its manufacturing method to overcome the problem. The phase-change memory device uses doped carbon layers as the parts of the electrodes. Since the doped carbon layers have high electrical conductivity and high carrier mobility, the phase-change memory device can be operated by low programming current and has a quick signal response and a fast transmission speed.

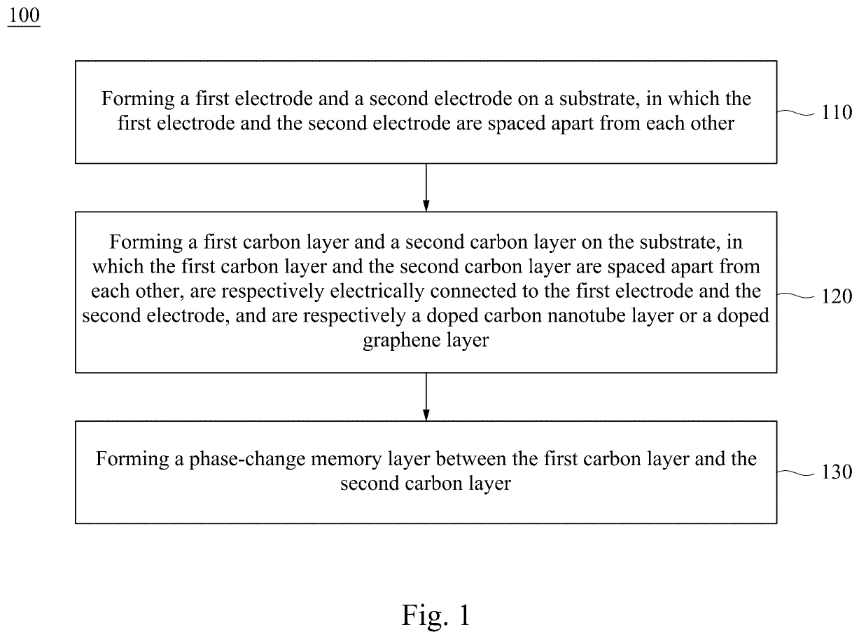

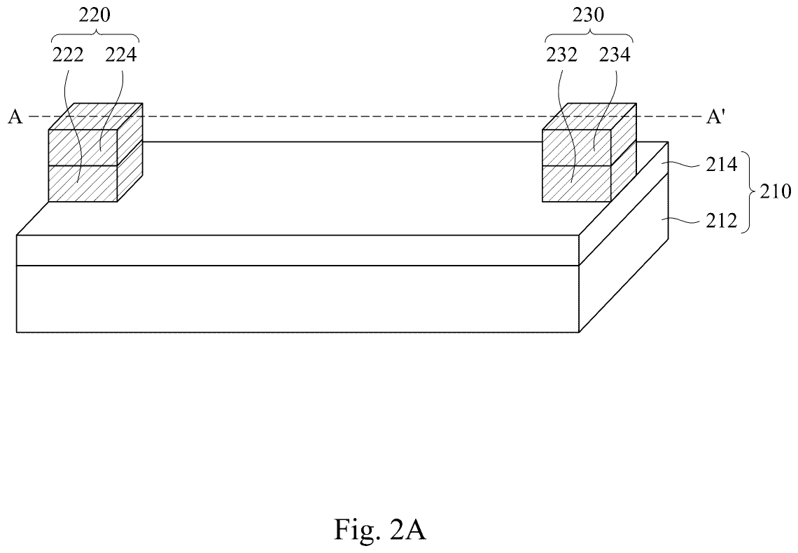

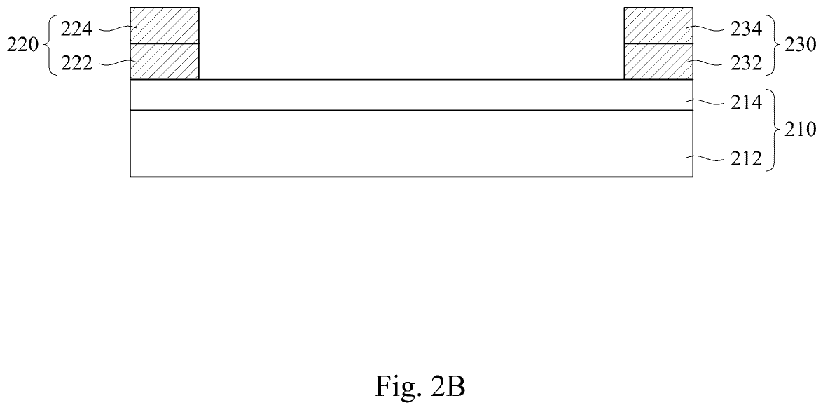

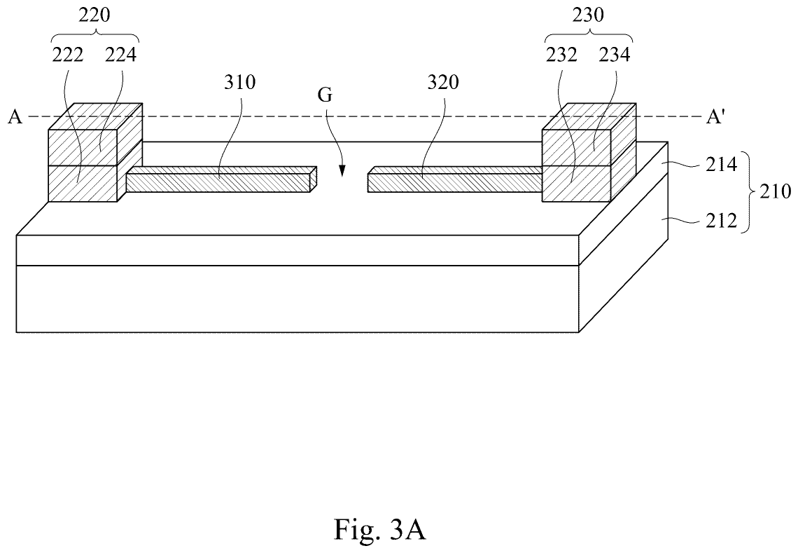

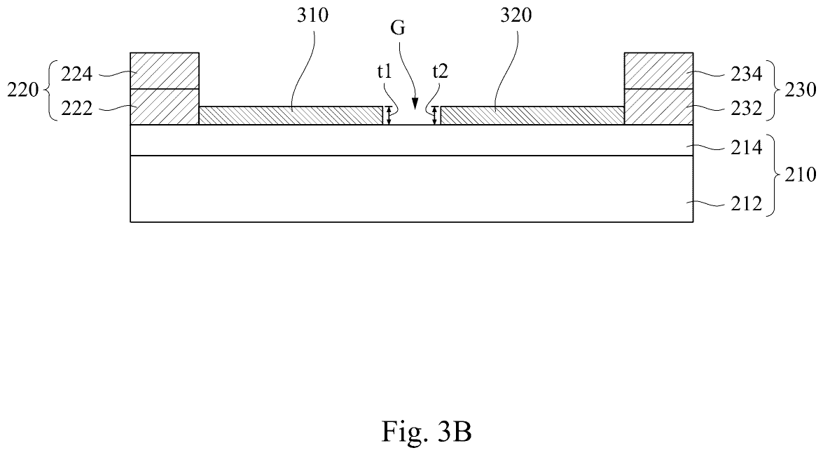

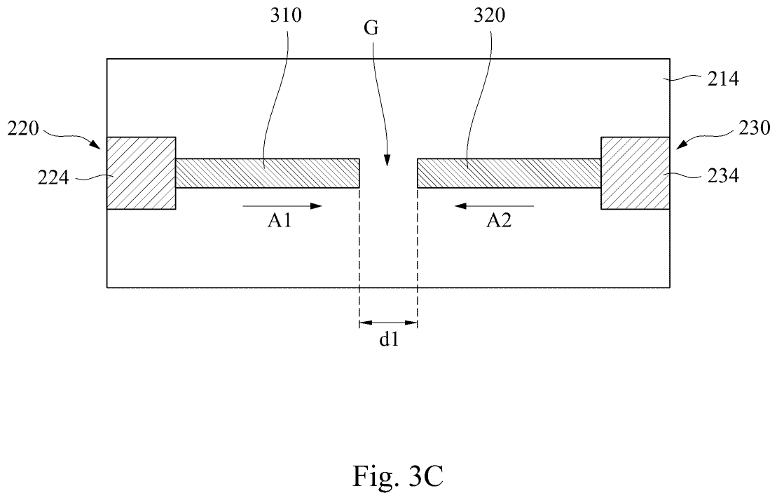

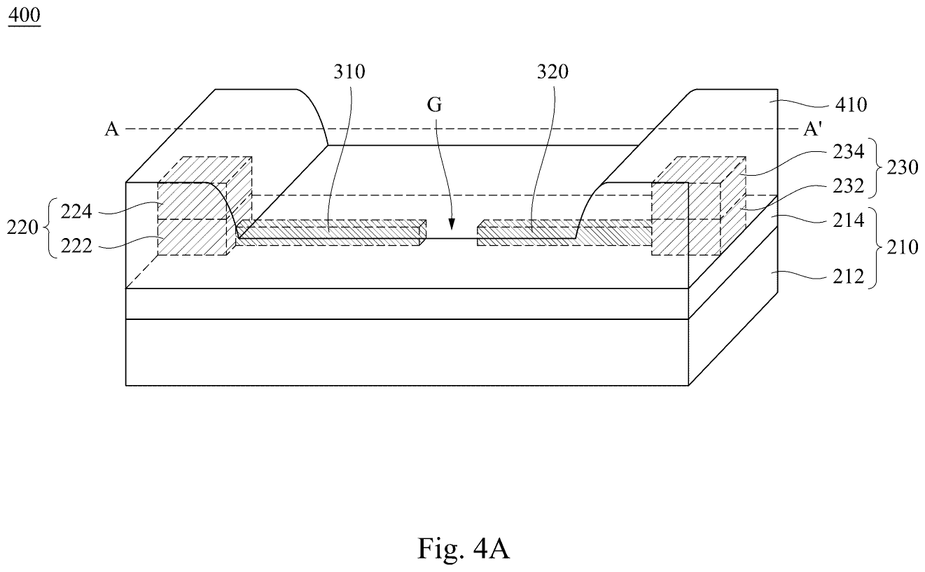

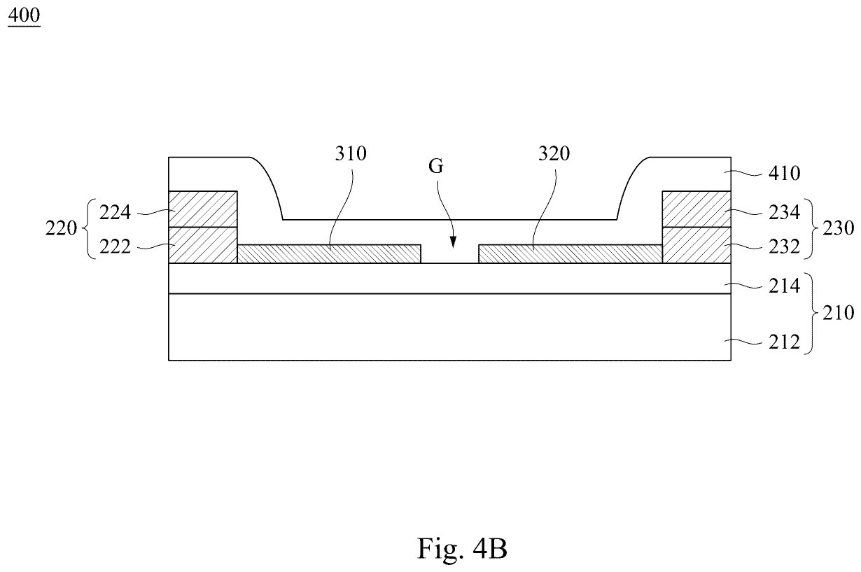

Please refer to FIG. 1, FIG. 2A, FIG. 2B, FIG. 3A, FIG. 3B, FIG. 3C, FIG. 4A, and FIG. 4B. FIG. 1 is a flowchart of a method 100 of manufacturing a phase-change memory device according to various embodiments of the present disclosure. The method 100 includes operation 110, operation 120, and operation 130. FIG. 2A, FIG. 3A, and FIG. 4A are perspective views illustrating intermediate stages of manufacturing a phase-change memory device according to various embodiments of the present disclosure. FIG. 2B, FIG. 3B, and FIG. 4B are respectively cross-sectional views of the phase-change memory device during the manufacturing process along the section lines A-A′ in FIG. 2A, FIG. 3A, and FIG. 4A. FIG. 3C is a top view of the phase-change memory device of FIG. 3A. The above-mentioned operations 110-130 will be described later with FIG. 2A to FIG. 4B.

Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all of the operations, steps, and/or features shown to achieve the embodiments of the present disclosure. In addition, each operation or step described herein may contain several sub-steps or actions.

In operation 110, as shown in FIG. 2A and FIG. 2B, a first electrode 220 and a second electrode 230 are formed on a substrate 210, in which the first electrode 220 and the second electrode 230 are spaced apart from each other. In some embodiments, the substrate 210 includes a semiconductor substrate 212 and an insulating layer 214 disposed on the semiconductor substrate 212. In some embodiments, the substrate 210 is a semiconductor-on-insulator (SOI) substrate. In some embodiments, the semiconductor substrate 212 is formed of commonly used semiconductor materials such as silicon (Si), silicon germanium (SiGe), gallium arsenide (GaAs), or the like. The semiconductor substrate 212 can be amorphous, polycrystalline, or monocrystalline. For example, the semiconductor substrate 212 is a highly doped p-type (p+) silicon substrate. In some embodiments, the insulating layer 214 includes SiO₂, Si₃N₄, or combinations thereof. In some embodiments, the first electrode 220 and the second electrode 230 respectively include W, TiN, Pt, Ti, Ru, Mo, Al, Cu, Ag, Au, or combinations thereof. For example, the first electrode 220 and the second electrode 230 are pure metal blocks. For example, the first electrode 220 and the second electrode 230 respectively include a metal stack containing different metals. In some embodiments, the first electrode 220 includes a first Ti layer 222 and a metal layer 224 disposed on the first Ti layer 222, and the metal layer 224 is a Pd layer, an Ag layer, or an Au layer. In some embodiments, the second electrode 230 includes a second Ti layer 232 and a metal layer 234 disposed on the second Ti layer 232, and the metal layer 234 is a Pd layer, an Ag layer, or an Au layer.

In operation 120, as shown in FIG. 3A, FIG. 3B, and FIG. 3C, a first carbon layer 310 and a second carbon layer 320 are formed on the substrate 210, in which the first carbon layer 310 and the second carbon layer 320 are spaced apart from each other, are respectively electrically connected to the first electrode 220 and the second electrode 230, and are respectively a doped carbon nanotube layer or a doped graphene layer. The first carbon layer 310 and the second carbon layer 320 are separated by a gap G and therefore are not in contact with each other. The first carbon layer 310 and the second carbon layer 320 can be viewed as extending portions of the first electrode 220 and the second electrode 230. Accordingly, the first electrode 220 and the first carbon layer 310 can be regarded as an electrode, and the second electrode 230 and the second carbon layer 320 also can be regarded as an electrode. In some embodiments, the first carbon layer 310 and the second carbon layer 320 are doped carbon nanotube layers and respectively include a plurality of carbon nanotubes with a length of 10 nm to 90 nm, such as 10, 20, 30, 40, 50, 60, 70, 80, or 90 nm. Therefore, it is beneficial for reducing the size of the structure shown in FIGS. 3A-3C.

Please still refer to FIG. 3A, FIG. 3B, and FIG. 3C. In some embodiments, forming the first carbon layer 310 and the second carbon layer 320 is performed by plasma-enhanced chemical vapor deposition (PECVD). If the insulating layer 214 is a SiO₂ layer, a doped carbon nanotube layer can be easily grew. In some embodiments, forming the first carbon layer 310 and the second carbon layer 320 includes the followings operations. The first electrode 220 including the first Ti layer 222 and the second electrode 230 including the second Ti layer 232 are formed on the substrate 210. A plurality of carbon nanotubes extending from the first Ti layer 222 is grew to form the first carbon layer 310. A plurality of carbon nanotubes extending from the second Ti layer 232 is grew to form the second carbon layer 320. In some embodiments, the first carbon layer 310 includes a plurality of carbon nanotubes extending from the first electrode 220 substantially along a first axial direction A1 towards the second electrode 230, and the second carbon layer 320 includes a plurality of carbon nanotubes extending from the second electrode 230 substantially along a second axial direction A2 towards the first electrode 220. The first axial direction A1 is the long axis direction of the carbon nanotubes in the first carbon layer 310, and the second axial direction A2 is the long axis direction of the carbon nanotubes in the second carbon layer 320. The first axial direction A1 and the second axial direction A2 are substantially parallel. In some embodiments, the first carbon layer 310 is in contact with the first electrode 220, and the second carbon layer 320 is in contact with the second electrode 230. In some embodiments, the first carbon layer 310 is in contact with the first Ti layer 222, and the second carbon layer 320 is in contact with the second Ti layer 232.

The first carbon layer 310 and the second carbon layer 320 respectively may be doped with N-type dopants or P-type dopants. The dopants can efficiently accelerate the transmission speed of the first carbon layer 310 and the second carbon layer 320 due to carrier concentration increase. The N-type dopants can have a better effect because electrons move faster than holes. When the first carbon layer 310 and the second carbon layer 320 are doped carbon nanotube layers, the dopants can increase the dispersibility of the carbon nanotubes and thus reduce aggregation of the carbon nanotubes, which can increase the electrical conductivities of the first carbon layer 310 and the second carbon layer 320. It is noted that the electrical conductivities of the first carbon layer 310 and the second carbon layer 320 are greater than that of the first electrode 220 and the second electrode 230. The first electrode 220 and the second electrode 230 serve as elements for delivering the electrical signals to other circuits. In some embodiments, the first carbon layer 310 and the second carbon layer 320 are respectively nitrogen-doped (N-doped) or phosphorus-doped. In some embodiments, the first carbon layer 310 and the second carbon layer 320 are boron-doped. In some embodiments, dopant concentrations of the first carbon layer 310 and the second carbon layer 320 are respectively 3 at % to 10 at %, such as 3, 4, 5, 6, 7, 8, 9, or 10 at %. If the dopant concentrations of the first carbon layer 310 and the second carbon layer 320 are in the above range, the first carbon layer 310 and the second carbon layer 320 can have high electrical conductivity for enhancing the transmission speed of the phase-change memory device. If the dopant concentrations are higher than 10 at %, the resistance value of the first carbon layer 310 and the second carbon layer 320 may increase.

Attention is now invited to FIG. 3B. It is noted that the first Ti layer 222 is beneficial for reducing the contact resistance between the first Ti layer 222 and the first carbon layer 310, and the second Ti layer 232 is beneficial for reducing the contact resistance between the second Ti layer 232 and the second carbon layer 320. In some embodiments, the thickness t1 of the first carbon layer 310 and the thickness t2 of the second carbon layer 320 are respectively 100 nm to 500 nm, such as 100, 150, 200, 250, 300, 350, 400, 450, or 500 nm. If the thickness t1 and the thickness t2 are in the above range, the first carbon layer 310 and the second carbon layer 320 can have high electrical conductivity for enhancing the transmission speed of the phase-change memory device. In some embodiments, the thickness t1 and the thickness t2 are less than or equal to the thicknesses of the first Ti layer 222 and the second Ti layer 232. Accordingly, the first carbon layer 310 is not in contact with the metal layer 224, and the second carbon layer 320 is not in contact with the metal layer 234.

Please refer to FIG. 3C. In some embodiments, a closest distance d1 between the first carbon layer 310 and the second carbon layer 320 is less than or equal to 100 nm, such as 10, 20, 30, 40, 50, 60, 70, 80, 90, or 100 nm. If the closest distance d1 is in the above range, the phase-change memory material (formed in the subsequent operations) between the first carbon layer 310 and the second carbon layer 320 can be switched under a small programming current (such as 0.5 mA), which is a set current or a reset current. If the closest distance d1 is small enough, the set current and/or reset current can be reduced to, for example, 0.01 mA. The closest distance d1 can be viewed as a length of the gap G. In some embodiments, the first carbon layer 310 has a length of 10 nm to 90 nm along the first axial direction A1, and the second carbon layer 320 has a length of 10 nm to 90 nm along the second axial direction A2. For example, the lengths are 10, 20, 30, 40, 50, 60, 70, 80, or 90 nm. Therefore, it is beneficial for reducing the size of the structure shown in FIG. 3C.

In operation 130, as shown in FIG. 4A and FIG. 4B, a phase-change memory layer 410 is formed between the first carbon layer 310 and the second carbon layer 320. More specifically, the phase-change memory layer 410 fills the gap G between the first carbon layer 310 and the second carbon layer 320. It is noted that the first carbon layer 310 and the second carbon layer 320 is separated by the phase-change memory layer 410 and can trigger the phase change by applying electrical signals to melt the phase-change memory layer 410. In some embodiments, forming the phase-change memory layer 410 between the first carbon layer 310 and the second carbon layer 320 includes forming the phase-change memory layer 410 to cover upper surfaces and side surfaces of the first carbon layer 310 and the second carbon layer 320 and to cover upper surfaces and side surfaces of the first electrode 220 an the second electrode 230. In some embodiments, the phase-change memory layer 410 includes GeTe, SbTe (such as Sb₂Te₃), BiTe, SnTe, AsTe, GeSe, SbSe, BiSe, SnSe, AsSe, InSe, InSb, InSbTe, GeSbTe (such as Ge₂Sb₂Te₅, GST), AglnSbTe, SiGeSb, TeGeSbS, AgSbSe, GeSbMnSn, AgSbTe, AuSbTe, AlSb, CrGeTe (such as Cr₂Ge₂Te₆), CuGeTe, ScSbTe, VO₂, MoO₂, V₂O₃, NbO₂, Fe₃O₄, FeS, Ta₂O₅, Ti₃O₅, Ti₂O₃, LaCoO₃, SmNiO₃, or combinations thereof, in which the element ratios of these materials can be adjusted arbitrarily.

Please still refer to FIG. 4A and FIG. 4B. The phase-change memory device 400 includes the substrate 210, the first electrode 220, the second electrode 230, the first carbon layer 310, the second carbon layer 320, and the phase-change memory layer 410. The first electrode 220 and the second electrode 230 are disposed on the substrate 210 and spaced apart from each other. The first carbon layer 310 and the second carbon layer 320 are disposed on the substrate 210 and spaced apart from each other. The first carbon layer 310 and the second carbon layer 320 are respectively electrically connected to the first electrode 220 and the second electrode 230 and are respectively a doped carbon nanotube layer or a doped graphene layer. The phase-change memory layer 410 is disposed between the first carbon layer 310 and the second carbon layer 320.

The phase-change memory device 400 can be switched to the on-state or off-state. When the phase-change memory device 400 is in the off-state, the phase-change memory layer 410 between the first carbon layer 310 and the second carbon layer 320 is in the amorphous state, which corresponds to the logic state “0.” When the phase-change memory device 400 is in the on-state, the phase-change memory layer 410 between the first carbon layer 310 and the second carbon layer 320 is in the crystalline state, which corresponds to the logic state “1,” and thus allows the current to flow through it. More specifically, the phase-change memory layer 410 is heated and/or melted by the current and therefore is transformed to the crystalline state with a low resistance value. If the first carbon layer 310 and the second carbon layer 320 are doped carbon nanotube layers, when a voltage is applied to the phase-change memory device 400 to switch it to the on-state, the broken carbon nanotubes can be reformed or reconnected. The amorphous state can be switched to the crystalline state by a set operation (set pulse), and the crystalline state can be switched to amorphous state by a reset operation (reset pulse). In some embodiments, the phase-change memory layer 410 is a GST layer, and the first carbon layer 310 and the second carbon layer 320 can trigger the GST transition by applying electrical signals. Since the first carbon layer 310 and the second carbon layer 320 are doped, the set current and/or reset current (programming current) used for switching behavior between crystallization and amorphization can be reduced to, for example, equal to or less than 0.05 mA, which is much less than the programming current (such as 0.5 mA) required in traditional phase-change memory devices. Please refer to FIG. 3C and FIG. 4B at the same time. If the closest distance d1 between the first electrode 220 and the second electrode 230 is small enough, the set current and/or reset current can be reduced to, for example, 0.01 mA.

In summary, the present disclosure provides a phase-change memory device and its manufacturing method. The phase-change memory uses doped carbon layers as the parts of the electrodes to control the switch between the amorphous state and the crystalline state. Since the doped carbon layers have high electrical conductivity and high carrier mobility, the phase-change memory device can be programmed with a small current and achieve a fast transmission speed.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A phase-change memory device, comprising:
a substrate;
a first electrode and a second electrode disposed on the substrate and spaced apart from each other;
a first carbon layer and a second carbon layer disposed on the substrate and spaced apart from each other, wherein the first carbon layer and the second carbon layer are respectively electrically connected to the first electrode and the second electrode and are respectively a doped carbon nanotube layer or a doped graphene layer; and
a phase-change memory layer disposed between the first carbon layer and the second carbon layer.

2. The phase-change memory device of claim 1, wherein the phase-change memory layer comprises GeTe, SbTe, BiTe, SnTe, AsTe, GeSe, SbSe, BiSe, SnSe, AsSe, InSe, InSb, InSbTe, GeSbTe, AglnSbTe, SiGeSb, TeGeSbS, AgSbSe, GeSbMnSn, AgSbTe, AuSbTe, AlSb, CrGeTe, CuGeTe, ScSbTe, VO₂, MoO₂, V₂O₃, NbO₂, Fe₃O₄, FeS, Ta₂O₅, Ti₃O₅, Ti₂O₃, LaCoO₃, SmNiO₃, or combinations thereof.

3. The phase-change memory device of claim 1, wherein the first carbon layer and the second carbon layer respectively comprises a plurality of carbon nanotubes with a length of 10 nm to 90 nm.

4. The phase-change memory device of claim 1, wherein thicknesses of the first carbon layer and the second carbon layer are respectively 100 nm to 500 nm.

5. The phase-change memory device of claim 1, wherein the first carbon layer comprises a plurality of carbon nanotubes extending from the first electrode substantially along a first axial direction, and the second carbon layer respectively comprises a plurality of carbon nanotubes extending from the second electrode substantially along a second axial direction.

6. The phase-change memory device of claim 1, wherein the first carbon layer is in contact with the first electrode, and the second carbon layer is in contact with the second electrode.

7. The phase-change memory device of claim 1, wherein a closest distance between the first carbon layer and the second carbon layer is less than or equal to 100 nm.

8. The phase-change memory device of claim 1, wherein dopant concentrations of the first carbon layer and the second carbon layer are respectively 3 at % to 10 at %.

9. The phase-change memory device of claim 1, wherein the first carbon layer and the second carbon layer are respectively nitrogen-doped or phosphorus-doped.

10. The phase-change memory device of claim 1, wherein the first electrode and the second electrode respectively comprises a Ti layer and a metal layer on the Ti layer, and the metal layer is a Pd layer, an Ag layer, or an Au layer.

11. A method of manufacturing a phase-change memory device, comprising:
forming a first electrode and a second electrode on a substrate, wherein the first electrode and the second electrode are spaced apart from each other;
forming a first carbon layer and a second carbon layer on the substrate, wherein the first carbon layer and the second carbon layer are spaced apart from each other, are respectively electrically connected to the first electrode and the second electrode, and are respectively a doped carbon nanotube layer or a doped graphene layer; and
forming a phase-change memory layer between the first carbon layer and the second carbon layer.

12. The method of claim 11, wherein forming the first carbon layer and the second carbon layer is performed by plasma-enhanced chemical vapor deposition.

13. The method of claim 11, wherein forming the first carbon layer and the second carbon layer comprises:
forming the first electrode comprising a first Ti layer and the second electrode comprising a second Ti layer on the substrate;
growing a plurality of carbon nanotubes extending from the first Ti layer to form the first carbon layer; and
growing a plurality of carbon nanotubes extending from the second Ti layer to form the second carbon layer.

14. The method of claim 11, wherein the first carbon layer and the second carbon layer are respectively nitrogen-doped or phosphorus-doped.

15. The method of claim 11, wherein forming the phase-change memory layer between the first carbon layer and the second carbon layer comprises forming the phase-change memory layer to cover upper surfaces and side surfaces of the first carbon layer and the second carbon layer.

16. The method of claim 11, wherein a closest distance between the first carbon layer and the second carbon layer is less than or equal to 100 nm.
